(19) United States
(12) Patent Application Publication
(10) Pub. No.: US 2004/0169595 A1
(43) Pub. Date: Sep. 2, 2004

(54) Method for encoding a stream of bits of a binary source signal into a stream of bits of a binary channel signal

(76) Inventors: Antonius Adrianus Cornelis Maria Kalker, Eindhoven (NL); Jeroen Jan Lambertus Horikx, Eindhoven (NL); Willem Marie Julia Marcel Coene, Eindhoven (NL)

Correspondence Address: PHILIPS INTELLECTUAL PROPERTY & STANDARDS, P.O. BOX 3001, BRIARCLIFF MANOR, NY, 10510, US

(21) Appl. No.: 09/817,095

(22) Filed: Mar. 26, 2001

(30) Foreign Application Priority Data
Mar. 30, 2000 (EP) 00201144.3

(51) Int. Cl. H03M 7/00; H03M 5/08

(52) U.S. Cl. 341/53; 341/50

(57) ABSTRACT

The invention relates to a method for encoding a stream of bits of a signal relating to a binary source into a stream of bits of a signal relating to a binary channel, the binary source comprising a main source and a secondary source, the main source being encoded in a main channel and the secondary source being encoded in a secondary channel, the secondary channel being embedded in the main channel in order to form the binary channel, wherein the binary channel is divided in blocks, each block comprising a number of user bits and that in at least one of the blocks the secondary channel also is used for encoding non-user bits.

The invention further relates to an encoder to carry out this method, a decoder to decode the stream of bits relating to the binary channel and a record carrier provided with the encoded signal in the form of optically detectable marks.

By means of the invention for example non-user data can be added that are used to prevent unauthorized copying.

The invention relates to a method for encoding a stream of bits of a signal relating to a binary source into a stream of bits of a signal relating to a binary channel, the binary source comprising a main source and a secondary source, the main source being encoded in a main channel and the secondary source being encoded in a secondary channel, the secondary channel being embedded in the main channel in order to form the binary channel.

The invention also relates to a method for decoding a stream of bits of a signal relating to a binary channel into a stream of bits of a signal relating to a binary source, the binary channel comprising a main channel and a secondary channel, the secondary channel being embedded in the main channel, and a stream of corrected bits of the binary channel relating to the main channel being used for correcting errors in the stream of bits of the binary channel relating to the secondary channel.

The invention also relates to an encoder comprising an input for receiving a stream of bits of a signal relating to a binary source and an output for providing a stream of bits of a signal relating to a binary channel, the binary source comprising a main source and a secondary source, the encoder comprising means for encoding the main source in a main channel, means for encoding the secondary source in a secondary channel, and means for embedding the secondary channel in the main channel in order to form the binary channel.

The invention further relates to a device for decoding a stream of bits of a signal relating to a binary channel into a stream of bits of a signal relating to a binary source, which device comprises decoding means conceived to decode a main channel, the decoding means being also conceived to decode a secondary channel, the secondary channel being embedded in the main channel, and to correct errors in the stream of bits of the binary channel relating to the secondary channel using a stream of corrected bits of the binary channel relating to the main channel.

The invention finally relates to a record carrier of the optical readable type in which information has been recorded as a pattern of optically detectable marks representing a binary channel arranged along a track.

The invention is applicable on information carriers with different kinds of channels codes. The information stored on these information carriers can, for example, be coded according to a runlength-limited (RLL) code. A RLL code is characterized by two parameters, (d+1) and (k+1), which stipulate the minimum and maximum runlength, respectively, that may occur in the code. For example, different DVD-formats, like DVD−RAM, DVD+RW or DVD−RW use a (d=2, k=10) RLL EFM⁺ code.

The basic functioning of a method and a device for en/decoding a stream of bits of a binary source signal into a stream of bits of a binary channel signal and vice versa can be understood from UK Patent Application GB 2 083 322 (PHQ 80007). In this case, the binary channel signal to be en/decoded is runlength limited. The stream of bits of a binary channel is obtained by reading out an information carrier with a focused laser beam, as is typical for optical information carriers. Using these RLL code and these reading out technique results in information carriers with a reasonable high capacity.

Under the conditions of the beam spot diameter (depending on the NA of the objective lens used) and the wavelength of the present laser beam, the capacity of the information carrier however can not be increased when keeping identical detection margins.

The non-published European patent applications, no. 99200873.0 (PHN 17.369 EP-P) and no. 99202061.0 (PHN 17.520 EP-P) describe methods to increase the capacity of the information carrier by addition of a secondary channel on top of a main channel. The main channel is a binary channel where pits and non-pits (lands) are related to two possible signal levels (below and above a threshold level).

In these earlier described methods the binary channel comprises a main channel and a secondary channel, the secondary channel being embedded in the main channel via multi-level coding or via merging bit coding. A stream of corrected bits of the binary channel relating to the main channel after decoding and error correction is re-encoded and used for correcting errors in the stream of bits of the binary channel relating to the secondary channel.

When establishing this interaction between error correction of the main channel and error correction of the secondary channel, a reliable secondary channel is created. It must be noted that the secondary channel exists by the grace of the main channel due to its hierarchical structure. Multi-level coding can be achieved in different ways. A physical parameter of the secondary channel can be used for multi-level coding, e.g. a so-called “peanut”-structure can be made, the depth and/or width of the pits and marks can be varied. Another possibility is to make use of the so-called merging bits for creating extra capacity.

In the case of multi-level coding, this coding is applied for runlengths Inₘᵢₙ or greater, in which nmin is a predetermined value, for example nₘᵢₙ=6. Apart from the main channel, which carries information in the occurrence of runlengths, extra capacity then is available in the amplitude level of longer runlengths (the secondary channel). The secondary channel is hierarchically dependent on the main channel, since bits relating to this secondary channel can only be accommodated at those locations in the channel bit stream, where the main channel coding uses longer runlengths. This secondary channel is realized via limited multi-level (LML) coding. The limitation consists of the choice that multi-level coding is only applied for runlengths Inₘᵢₙ or greater, in which nₘᵢₙ is a predetermined integer.

In the case of merging bit-coding, use is made of the fact that in the EFM channel code as used for CD, 8 source bits are encoded into 14 channel bits+3 merging bits. Merging bits can be used to prevent violation of the runlength constraint d=2 and k=10 of the EFM channel code or for DC-control to keep the overall DC value of the bits at about zero. Depending on the preceding EFM word and the next EFM word, i.e. the words before and after a particular merging bit pattern (MBP) respectively, 1-4 choices for the MBP are possible. When more than one choice is possible, use can be made of this freedom of choice by using only some of the MBP's for DC control and the others to generate extra capacity.

Since the two EFM words before and after the merging bits determine the number of MBP's that are possible, the merging bit channel is hierarchically dependent on the EFM main channel. In order to obtain a reliable detection of the bits of the MBP's, like in the multi-level decoding, use is made of the error correction in the main channel by re-encoding the EFM channel bits and using these for correcting errors in the stream of MBP-bits.

Since both in MBP-coding as in multi-level coding the secondary channel is hierarchically dependent on the main channel, the number of possible MBP coding bits or multi level coding bits varies. Of course, it is desired that a predetermined number of secondary bits can be accommodated in a predetermined quantity of EFM words, for example within a block of 64 kBytes user bits. In order to obtain this, it is determined, based on the fact that the distribution of the longer effects in multi-coding or of the MBP bits in MBP coding is Gaussian, which number of secondary bits can be accommodated with a certain probability. In the earlier mentioned methods one chooses the number of longer effects, i.e. runlengths with Inₘᵢₙ>6, or the number of MBP coding bits that is used for the secondary channel to be 8 standard deviations (8σ) smaller than the average number of longer effects or MBP codes. By doing this the probability that a block will not contain a sufficient number of longer effects or MBP's that can be used for coding, is only about 6×10⁻¹⁶.

As an example some characteristics of applying the method of embedding a secondary channel in a main channel are given. For a maxentropic d=2, k=10 RLL sequence, the extra capacity available in the secondary/LML channel for Inₘᵢₙ=6 amounts to 11.5% on average. For long enough data sequences, the distribution of the extra capacity in the secondary/LML channel becomes very narrow. For a complete sector of 64 kb, a capacity of 11.3% can practically always be guaranteed (probability of 1-10⁻¹⁵), i.e. the probability that it can not be guaranteed is smaller than the miscorrection probability of the to be discussed error correction coding (ECC) (probability of 10⁻¹²). If the same overhead for ECC applies to both main/RLL and secondary/LML channels, then only the overhead for the channel coding of the secondary/LML-source bits is to be taken into account.

The LML-channel code is essentially a DC-free d=0 code which allows enabling slicer control on the additional amplitude levels in pits and lands. Even for the low-rate 8-to-9 d=0 code (with an overhead of 12.5%; see U.S. Pat. No. 5,642,113 (PHN 14789)) a final capacity increase of about 10.0% is achievable on top of the capacity of the RLL channel.

The object of the invention is to increase the capacity of an information carrier of the present type even further.

The method according to the invention is characterized in that the binary channel is divided in blocks, each block comprising a number of user bits and that in at least one of the blocks the secondary channel also is used for encoding non-user bits.

The present invention is based on the insight that since only a part of the real capacity of the secondary channel is used for encoding, because of the above described probability restraints, additional capacity remains that can be used for other purposes than the encoding of user data.

In particular this additional capacity can be used for coding information of which the correct decoding has not to be guaranteed with an extremely high probability. Such information for example can consist of information that is present in an identical form in more than one or even all blocks of user bits and for example can be information that is used for identifying a CD for authenticity purposes in order to prevent unauthorized copying, such information can comprise a key consisting of non-user bits.

According to a first aspect of the invention, the secondary channel is embedded in the main channel by multi-level coding, preferably level coding applied only to runlengths Inₘᵢₙ or greater, wherein nₘᵢₙ is a predetermined integer.

According to a second aspect of the invention merging bit coding is applied to embed the secondary channel in the main channel.

According to a third aspect of the invention, in the case of multi-level coding, only one non-user bit per block is encoded by giving all runlengths Inₘᵢₙ or greater that are not used for the encoding of the secondary channel one predetermined value, depending on the value of the non-user bit.

In another embodiment of this third aspect all runlengths Inₘᵢₙ or greater that are not used for the encoding of the secondary channel are given alternatively a first binary value and a second binary value, when a first value of the non-user bit has to be encoded, and are given alternatively the second binary value and the first binary value, when a second value of the non-user bit has to be encoded. The latter scheme has the advantage that on a block base the DC content is not effected by the encoding of the additional key bit.

According to a fourth aspect of the invention the additional capacity of the secondary channel is used to vary the number of LML bits of a block, with respect to the number of bits in the primary channel of that block. In a simple scheme two different ratios can be used, when the ratio in a block has a first value a first binary value is encoded and when the ratio has a second value a second binary value is encoded.

For copy protection purposes the encoding of one key bit per sector in general is more than sufficient to obtain a robust protection. Known copy protection schemes, such as wobble-key protection, use only 64 bits per disk.

According to a fifth aspect of the invention scrambling of the primary channel bits is used to influence the number of available secondary channel bits. By doing so a number of different ratios between the number of LML bits and the number of primary channel bits can be defined. Each ratio, or range of ratios, corresponds with a certain data-word. When M ratios or disjunct ranges of ratios are available, datawords of log₂ (M) bits can be registered.

By using erasure information from the main channel when correcting errors in the stream of bits of the binary channel relating to the secondary channel, the traditional error correction of the secondary channel (before referred to as the second stage of error correction for the secondary channel) can be improved. Erasure information is information indicating the presence of possible errors in the bit stream and is generated during the error correction of the main channel. The number of errors which can be corrected by the second stage of error correction for the secondary channel is increased using this erasure information.

The encoder in accordance with the invention is characterized in that means are provided to divide the binary channel in blocks, each block comprising a number of user bits and that in at least one of the blocks the secondary channel also non-user bits are encoded.

The device in accordance with the invention is characterized in that said decoding means are also conceived to decode non-user bits in the secondary channel.

Another device in accordance with the invention is characterized in that the device further comprises reading means for reading out an information carrier to obtain the stream of bits of the binary channel signal.

The record carrier in accordance with the invention is characterized in that the binary channel is divided in blocks, each block comprising a number of user bits and that in at least one of the blocks the secondary channel bits comprise non-user bits.

The invention will be further described in the following figure description in which

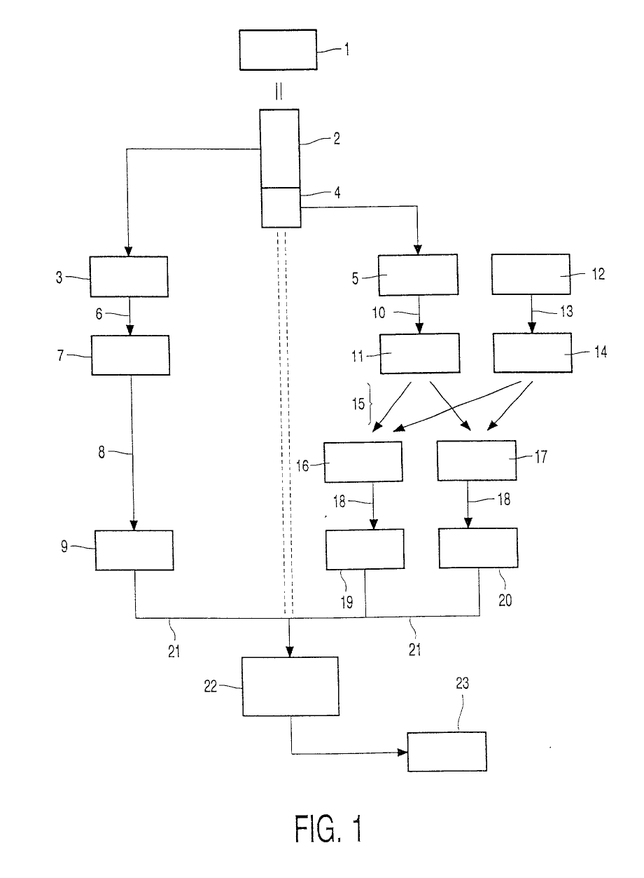

FIG. 1 shows a first embodiment of a method for encoding, according to the invention.

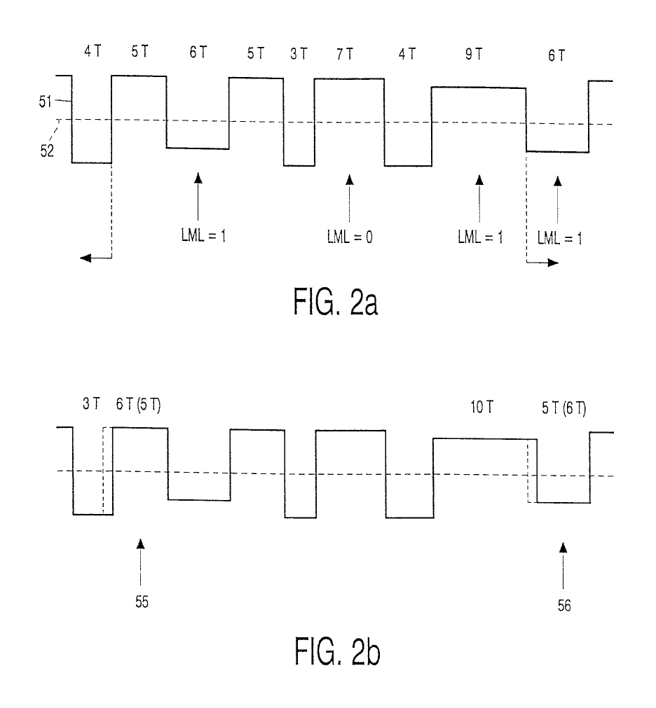

FIG. 2a, b shows the presence and origin of bit slips in the secondary channel,

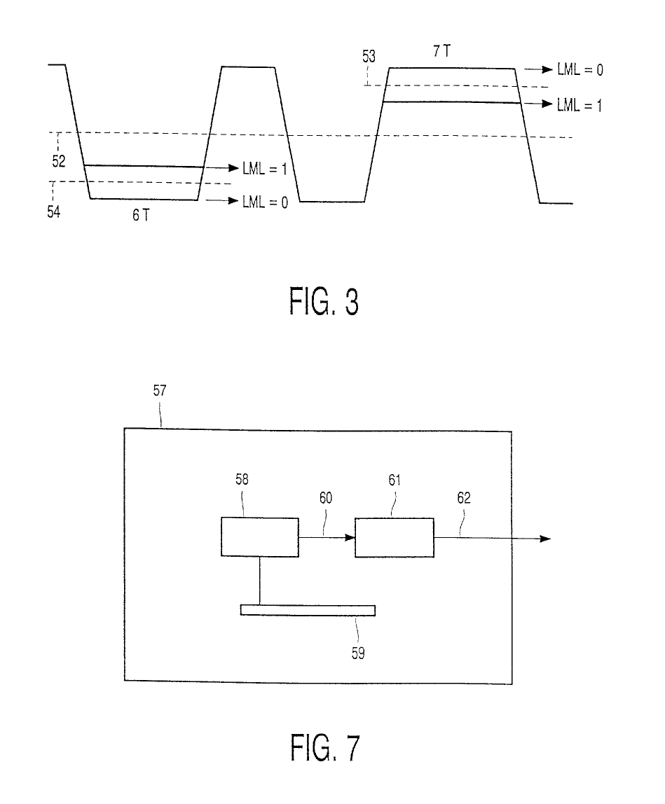

FIG. 3 shows an embodiment of the detection of the secondary channel,

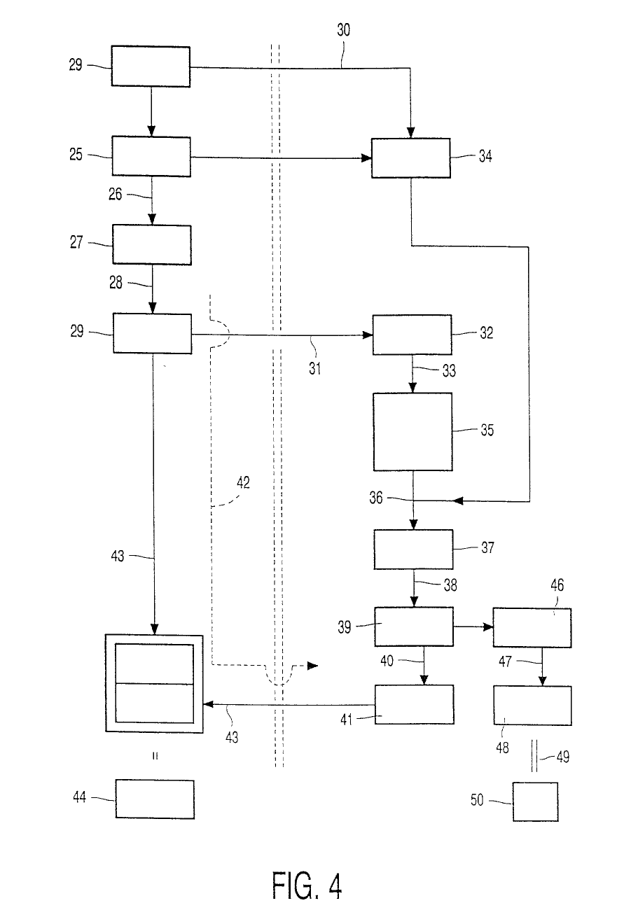

FIG. 4 shows an embodiment of a method for decoding according to the invention,

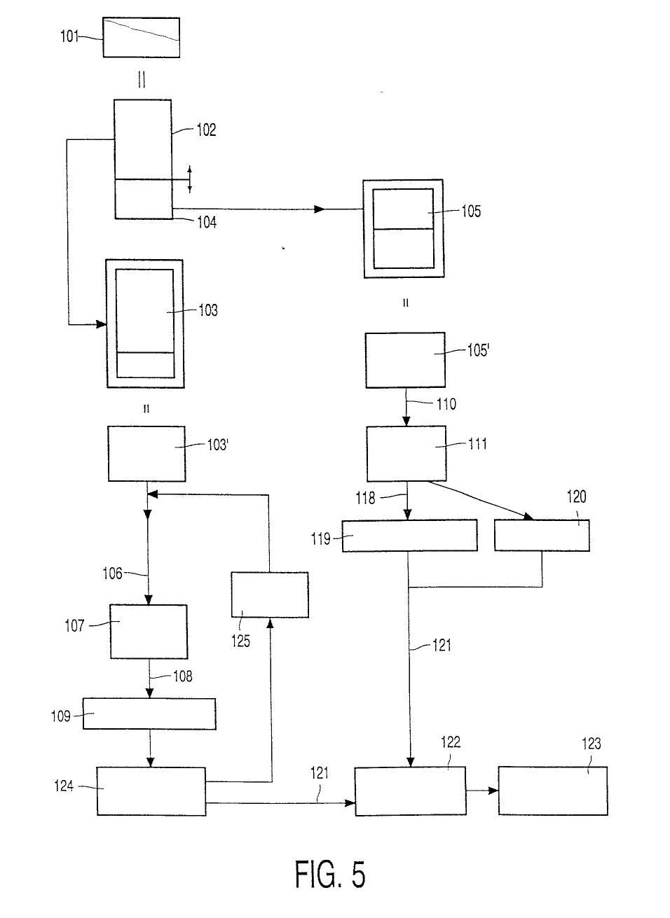

FIG. 5 shows a second embodiment of a method for encoding according to the invention,

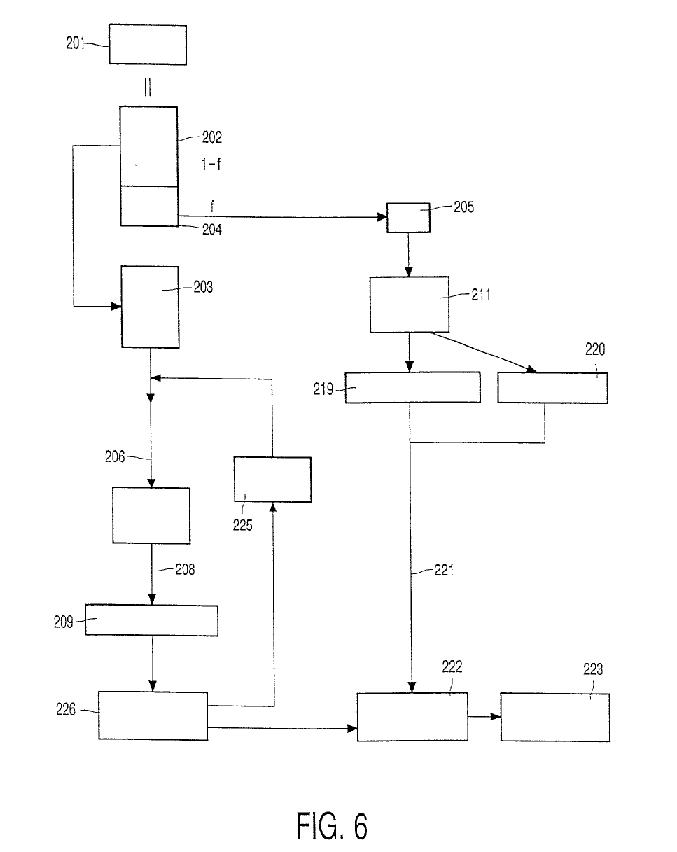

FIG. 6 shows a third embodiment of a method for encoding according to the invention, and

FIG. 7 shows an embodiment of a device for decoding according to the invention.

FIG. 1 shows an embodiment of a method for encoding. User data 1 is partitioned between the main channel 2, comprising main user bits 3, and the secondary channel 4, comprising secondary user bits 5. In step 6, error correction is applied on the main user bits 3, yielding main source bits 7. These main source bits 7 comprise of user data and parities generated in step 6. In step 8, encoding of the main source bits 7 yields the main channel bits 9 without the amplitude information. The encoding in step 8 can for example be accomplished via a standard RLL channel code, e.g. EFM⁺, well known to a person skilled in the art.

In step 10, error correction is applied on the secondary user bits 5, yielding secondary source bits 11. These secondary source bits 11 comprise of user data and parities generated in step 10. The secondary source bits 11 are further split into a secondary pit channel 12, with secondary pit bits and an secondary land channel 13, with secondary land bits.

On secondary LML non-user bits 12 in step 13 error correction is applied yielding secondary non-user fill bits 14. These non-user fill bits in step 15 first are added to the secondary source bits 11 forming secondary pit source bits+non-user pit fill bits 16 and secondary land source bits+non-user land fill bits 17.

A very simple non-user bit coding can be obtained when only one non-user bit per block has to be encoded, by making all non-user bits=“0” when the non-user bit has a first binary value and=“1” when the non-user bit has a second binary value. Another possibility is to make all non-user bits alternatively “1” and “0” when the non-user bit has a first binary value and alternatively “0” and “1” when the non-user bit has a second binary value.

In step 18, a d=0 DC-free channel code is used for encoding both channels to generate secondary pit channel bits 19 and secondary land channel bits 20. An example of such a d=0 channel code is the 8-to-9 d=0 code as can be found in U.S. Pat. No. 5,642,113 (PHN 14789). The DC-free property of the code used for encoding is needed in order to retrieve (during the secondary channel detection) the slicer level from the measured waveform for detection of the secondary bits.

The secondary channel bits yield the amplitude information to be incorporated into the waveform that is to be generated from the secondary channel bitstream. In step 21, the main channel bits 9, the secondary pit channel bits 19 and the secondary land channel bits 20 are combined into the assembled channel bits 22. These assembled channel bits 22 are then written on an information carrier 23.

When writing the assembled channel bits on the information carrier the multi-level coding is only applied for runlengths Inₘᵢₙ or greater, in which Inₘᵢₙ is a predetermined value. This multi-level coding can be performed in different ways. For example, the pits and lands can be mastered in a so-called “peanut”-structure which is realized by turning off the laser at a predetermined place and for a predetermined time in case of a pit and by turning on the laser at a predetermined place and for a predetermined time in case of a land. Also a narrower pit structure can be used for multi-level coding. The method according to the invention is not limited to multi-level coding of a particular kind. In the present embodiment limited multi-level coding is used, but the method according to the invention is not limited to this so-called limited-level coding.

The secondary channel 4 is dependent on the main channel 2 due to the linking of the secondary amplitude-effect with the longer runlengths. The detection problem caused by the hierarchy between main and secondary channels will be explained for the case Inₘᵢₙ=6. Suppose for instance that a channel error occurred in the main channel (a simple transition shift) which turned an I5 into an I6. The first run does not carry an additional bit whereas the second one does. Therefore, straightforward detection of the secondary channel yields a bit-insertion. A bit-deletion takes place when an I6 is turned into an I5 during RLL detection. In fact, simple transition shifts in the RLL channel can lead to bit slips (bit insertions and bit deletions) in the LML channel. This is further explained with reference to FIG. 2.

FIG. 2 shows the presence and origin of bit slips in the secondary channel. In FIG. 2a an original RLL sequence 51 is shown with runlengths 4T, 5T, 6T, 5T, 3T, 7T, 4T, 9T and 6T, as is indicated in this Figure above the sequence 51. The dashed line 52 indicates the normal slicer level used for detection of the main channel. With LML=0 and LML=1 under the sequence 51 is indicated what sort of secondary/LML-source bit is present is the indicated runlength. The meaning of LML=0 and LML=1 is explained using FIG. 3.

FIG. 3 shows an embodiment of the detection of the secondary channel. Secondary channel-detection is performed on the basis of the signal waveform and checks via a slicer operating on the amplitude e.g. in the middle of the run if runs have the secondary channel amplitude-effect or not. One stores the information of the secondary channel-effect on all runs on a symbol-by-symbol basis (for symbols of length equal to n channel bits). One could also decide just to store this information for all runs ranging from an I(nₘᵢₙ−1) and larger, in case single-bit transition shifts are the main error source in the main channel. The storage on a symbol-by-symbol basis is needed in order to avoid problems with missing runs in the main channel, i.e. short runlengths of which the signal waveform does not reach beyond the slicer level of the main channel, which can occur with low probability.

For runlengths 6T and 7T it is indicated how the detection of the secondary/LML bits is done. The dashed line 53 indicates the LML-land slicer level used for detection of the secondary/LML-land bits. The dashed line 54 indicates the LML-pit slicer level used for detection of the secondary/LML-pit bits. Depending on the detection with these slicer levels 53 and 54, the character of the LML-bit is indicated with LML=0 or LML=1. The slicer levels 53 and 54 are used to decide whether runs have the secondary channel amplitude-effect or not.

In FIG. 2b the principle behind LML-bit insertion and LML-bit deletion is shown. Arrow 55 indicates the presence of LML-bit insertion as the original runlength 5T from FIG. 2a is detected as a 6T runlength. In this case a bit-insertion takes place when an I5 is turned into an I6 during RLL detection if for the parameter nₘᵢₙ is nₘᵢₙ=6. Arrow 56 indicates the presence of LML-bit deletion as the original runlength 6T from FIG. 2a is detected as a ST runlength. In this case a bit-deletion takes place when an I6 is turned into an I5 during RLL detection if for the parameter nₘᵢₙ is nₘᵢₙ=6.

The solution to the above problem of bitslips is described in FIG. 4. It shows an embodiment of a method for decoding according to the invention. The main channel bits 25 are detected out of the signal waveform 24. The method for decoding the main channel bits into the main user bits is just the standard one, well-known to a person skilled in the art: in step 26 the main channel bits 25 are decoded into the main source bits 27, in step 28 the error correction is applied on the main source bits 27, which yields the corrected main source bits 29. These corrected main source bits 29 comprise user data plus parities.

In this embodiment of a method for decoding according to the invention the detection of the secondary channel requires the following: In step 30 secondary channel detection is accomplished. During the detection of the main channel, channel errors may lead to erroneous runlengths in the main channel bitstream, i.e. detected runlengths may be different from encoded runlengths. Therefore, one assumes first that each runlength carries a potential secondary channel bit, and secondary channel detection is performed on each runlength. Notice that only if the encoded runlength is not smaller than Inₘᵢₙ, then an actual secondary channel bit is detected. In step 30, secondary channel detection is performed on the basis of the signal waveform and checks via a slicer operating on the amplitude in the middle of the run if runs have the secondary channel amplitude-effect or not (i.e. if a potential LML bit has value 1 or 0). One stores the information of the secondary channel effect on all runs on a symbol-by-symbol basis in block 34. One could also decide just to store this information for all runs ranging from an I(nₘᵢₙ−1) and larger, in case single-bit transition shifts are the main error source in the main channel. The storage on a symbol-by-symbol basis is needed in order to avoid problems with missing runs, i.e. short runlengths of which the signal waveform does not reach beyond the slicer level of the main channel.

After error correction of the main channel in step 28, in step 31 the corrected main source bits 29 are re-encoded yielding the exact main channel bitstream 32. In step 33, this exact main channel bitstream 32 is used to yield the correct position of all runs in the main channel bit stream and is shown in block 35. In step 36, this exact knowledge of the occurrence of the long runlengths, stored in block 35, is combined with the secondary channel info about potential secondary channel bits, stored in block 34, which yields the detected secondary channel bits 37. In step 38, decoding of the secondary channel yields the secondary channel user bits 39. In step 40, traditional error correction of the secondary channel finally yields the corrected secondary channel user bits 41.

In step 43, the secondary channel user data 41 are combined with the user data of the main channel 29 (i.e. the corrected main source bits), to reassemble the complete user data 44.

Since the number of LML bits per block is known, the detected non-user bits 46 can be extracted from the secondary channel bits in step 45. In step 47 traditional error correction of the non-user bits yields the corrected non-user bits 48. In step 49 the parities are removed to form the original non-user bits 50, i.e. the key.

The embodiment as described above is to be considered as one example to which the method of decoding according to the invention is applicable. The error correction of the secondary channel (step 40) can be improved via information generated during the error correction of the main channel (step 28). This is indicated by the dashed line 42. E.g. information about burst-errors generated from the main channel error correction can be used as erasure information for the error correction of the secondary channel.

The same principle as described in the above for LML coding of non-user bits mutatis mutandis also can be applied for merging bit coding.

FIG. 5 shows a second embodiment of the invention for encoding a non-user or key bit in each block of user bits. In this figure blocks and steps similar to those described in connection with FIG. 1 have the reference numbers of these figures increased by 100. Those similar steps will not be described again in connection with FIG. 5. In this embodiment no key bits are added to the secondary user bits as in FIG. 1, but the ratio of the number of user bits N per block and the number of secondary user bits is varied. When only a key bit having a first and a second binary value is to be encoded from the total of user bits f a first number f′ of LML bits is chosen as secondary channel bits 10, and when a second binary value has to be encoded a second number of LML bits f″ is chosen as secondary channel bits 20. In case of the first binary value of the key, the number of user bits for the main channel is f-f′ and when the key has the second binary value, the number of user bits for the main channel is f-f″.

When instead of a single key bit a codeword has to be stored, a number of different ratios or ranges of ratios can be chosen by varying f′, the number of secondary user bits. When for example a number of M different ratios is available a codeword of log₂ M bits can be encoded.

It is a requirement for correct error correction that a total number of bits entered into the error correction circuit is constant. Therefore zero-padding is applied to the user bits for the main channel 102 and the secondary channel 105, the number of bits varying with the key to be encoded, to obtain a constant number of main channel bits 103′ and secondary channel bits 105′ for the error correction.

Further it can be necessary to scramble the main channel user bits in order to obtain the possibility to encode a sufficient number of secondary user bits without affecting the probability that no sufficient space is available in a certain RLL-word.

This is shown in FIG. 5 by the units 124 and 125. In step 124 it is determined whether predetermined scramble aims have been obtained, if so step 121 is chosen, if not, in scrambler step 125 the RLL channel bits are scrambled again and fed back to the error correction step 106. Decoding of the binary channel encoded by means of the method of FIG. 5 can take place with a decoder similar to that of FIG. 4, by comparing the number of corrected user bits obtained by step 43 with the number of corrected LML user bits obtained by step 40 and determining the ratio of these numbers in order to detect whether the ratio is 1-f′/f1 or 1-f″/f″, or any other ratio in case of more than two ratios. Depending on the detected ratio a key bit “1” or “0” is determined.

In still another embodiment of the possibility to encode a key by making use of the secondary channel a fixed ratio f between the capacity of the primary and secondary channel is used, so that no zero-padding is required.

FIG. 6 shows a block scheme of this embodiment. In this block scheme all steps and blocks that are similar to the steps and blocks in FIG. 1 have the same reference numeral, but are increased by 200. These steps and blocks will not be described in detail again. The additional information (key) for copy protection comprising non-user bits is implemented by controlling the overcapacity of the LML channel by means of an appropriate scrambling. When it is determined in block 226 that the overcapacity of the LML channel is insufficient a new scrambling is applied by scrambler 225 and the scrambled bits are fed back to the error coding step 206. The ratio between the primary channel bits and the secondary channel bits obtained by selecting a certain scrambler also in this embodiment are used to encode the non-user or key bits. In order to use a correct descrambler during decoding, identification data, an ID, of the scrambler actually used is stored in a separate field on the information carrier. During decoding this field is read and the correct descrambler in the decoder is selected.

By applying the encoding method of FIGS. 5 and 6 to a selected set of blocks, a low-rate subliminal channel (sub-LML channel) is created that is secure, i.e. difficult to read by a person trying to obtain an illegal copy, and fragile, i.e. it is lost when a copy is made because when for example in a first step a copy of the content of a CD encoded according to the invention is made on a hard-disk, and when that information in a second step is written on a recordable CD, the original relation between the main channel user bits and LML channel user bits gets lost. For a secure copy protection the data in the sub-LML channel preferably is linked to the watermarks that are present in the audio and/of video content of the CD.

FIG. 7 shows an embodiment of a device 57 for decoding according to the invention. The device comprises reading means 58 for reading out an information carrier 59, e.g. a DVD-ROM. These reading means 58 comprise an optical system for generating a focussed light spot on the information carrier 59 and a detector for detecting the reflected light spot. The reading means 58 produce a stream of bits of a signal relating to a binary channel 60. This stream of bits of a signal relating to a binary channel 60 is decoded in a decoder 61 into a stream of bits of a signal relating to a binary source 62. The decoder 61 comprises standard means for decoding a RLL channel code, e.g. (EFM⁺)⁻¹ and means for error correction, e.g. CIRC-correction, both well known to a person skilled in the art. The decoder 61 further comprises means for decoding a secondary channel according to the method according to the invention. The stream of bits of a signal relating to a binary source 62 is outputted by the device 57 and can be further processed, e.g. for playing audio information, or screening video information.

Whilst the invention has been described with reference to preferred embodiments thereof, it is to be understood that these are not limitative examples. Thus, various modifications may become apparent to those skilled in the art, without departing from the scope of the invention, as defined in the claims.

Further, the invention lies in each and every novel feature or combination of features.

1. A method for encoding a stream of bits of a signal relating to a binary source into a stream of bits of a signal relating to a binary channel, the binary source comprising a main source and a secondary source, the main source being encoded in a main channel and the secondary source being encoded in a secondary channel, the secondary channel being embedded in the main channel in order to form the binary channel, characterized in that the binary channel is divided in blocks, each block comprising a number of user bits and that in at least one of the blocks the secondary channel also is used for encoding non-user bits.

2. Method according to claim 1, wherein the secondary channel is embedded in the main channel by multi-level coding.

3. Method according to claim 2, wherein level coding is applied only to runlengths Inₘᵢₙ or greater, wherein nₘᵢₙ is a predetermined integer.

4. Method according to claim 1, wherein merging bit coding is applied to embed the secondary channel in the main channel.

5. Method according to claims 2 or 3, wherein one non-user bit per block is encoded by giving all runlengths Inₘᵢₙ or greater that are not used for the encoding of the secondary channel one predetermined value, depending on the value of the non-user bit.

6. Method according to claims 2 or 3, wherein all runlengths with Inₘᵢₙ that are not used for the encoding of the secondary channel are given alternatively a first binary value and a second binary value when a first value of the non-user bit has to be encoded and are given alternatively the second binary value and the first binary value when a second value of the non-user bit has to be encoded.

7. Method according to claims 2 or 3, wherein the ratio of the number of LML bits of a block with respect to the number of bits in the primary channel of that block is varied, for encoding non-user bits.

8. Method according to claim 7, wherein the number of LML bits is arranged by selecting a scrambler for the primary channel bits.

9. Method according to claim 7 or 8, wherein at least two different ratios are used, when the ratio in a block has a first value a first binary value is encoded and when the ratio has a second value a second binary value is encoded.

10. Method according to claim 9, wherein more than two different ratios or ranges of ratios are used to encode non-user bits.

11. An encoder comprising an input for receiving a stream of bits of a signal relating to a binary source and an output for providing a stream of bits of a signal relating to a binary channel, the binary source comprising a main source and a secondary source, the encoder comprising means for encoding the main source in a main channel, means for encoding the secondary source in a secondary channel, and means for embedding the secondary channel in the main channel in order to form the binary channel, wherein means are provided to divide the binary channel in blocks, each block comprising a number of user bits and wherein in at least one of the blocks the secondary channel also non-user bits are encoded.

12. Encoder according to claim 11, wherein the means for embedding apply multi-level coding.

13. Encoder according to claim 11, wherein the means for embedding apply merging bit coding.

14. Method for decoding a stream of bits of a signal relating to a binary channel into a stream of bits of a signal relating to a binary source, the binary channel comprising a main channel and a secondary channel, the secondary channel being embedded in the main channel, and a stream of corrected bits of the binary channel relating to the main channel being used for correcting errors in the stream of bits of the binary channel relating to the secondary channel, wherein the stream of bits of the signal relating to the binary channel is encoded in accordance with the method of any of the claims 1-10.

15. A device for decoding a stream of bits of a signal relating to a binary channel into a stream of bits of a signal relating to a binary source, which device comprises decoding means conceived to decode a main channel, the decoding means being also conceived to decode a secondary channel, the secondary channel being embedded in the main channel, and to correct errors in the stream of bits of the binary channel relating to the secondary channel using a stream of corrected bits of the binary channel relating to the main channel, wherein said decoding means further are conceived to decode non-user bits in the secondary channel.

16. A device according to claim 15, wherein the device further comprises reading means for reading out an information carrier to obtain the stream of bits of the binary channel signal.

17. A record carrier of the optical readable type in which information has been recorded as a pattern of optically detectable marks representing a binary channel arranged along a track, wherein the detectable marks comprise main channel bits and secondary channel bits, which are embedded in the main channel bits, the main channel bits and the secondary channel bits forming a binary channel, wherein the binary channel is divided in blocks, each block comprising a number of user bits and wherein in at least one of the blocks the secondary channel bits comprise non-user bits.

18. A record carrier according to claim 17, wherein the secondary channel bits are embedded in the main channel bits by means of multi-level coding.

19. A record carrier according to claim 18, wherein the multi-level coding is applied only to runlengths Iₙ₋ₘᵢₙ or greater, wherein n-min is a predetermined integer.

20. A record carrier according to claim 17, wherein the secondary channel bits are embedded in the main channel bits by means of merging bit coding.
